(19) United States
(12) Patent Application Publication
(10) Pub. No.: US 2011/0199736 A1
(43) Pub. Date: Aug. 18, 2011

(54) POWER CONVERTER

(75) Inventors: Naoki Sawada, Anjo-shi (JP); Hiroshi Fujita, Kuwana-shi (JP); Hironori Oobayashi, Kariya-shi (JP); Taijirou Momose, Kariya-shi (JP)

(73) Assignee: DENSO CORPORATION, Kariya-city (JP)

(21) Appl. No.: 13/027,559

(22) Filed: Feb. 15, 2011

(30) Foreign Application Priority Data
Feb. 15, 2010 (JP) 2010-030545

(51) Int. Cl. H05K 7/20

(52) U.S. Cl. 361/722

(57) ABSTRACT

An inverter device has a control unit, a power unit, and a capacitor unit. The power unit has six semiconductor devices. Each semiconductor device has a semiconductor module and a pair of heat sinks disposed in both sides of the semiconductor module. The heat sinks are arranged in a ventilation path of cooling air. An, accommodation chamber of a control unit 1b communicates with the ventilation path of the cooling air.

### CROSS-REFERENCE TO RELATED APPLICATION

This application is based on and claims the benefit of priority from earlier Japanese Patent Application No. 2010-30545 filed Feb. 15, 2010, the description of which is incorporated herein by reference.

### TECHNICAL FIELD

The present disclosure relates to a power converter that has a heat sink to cool a semiconductor module.

### BACKGROUND

JP-A-2005-73374 discloses a multiphase electric power converting device that arranges a plurality of semiconductor modules and a cooling device between a control circuit and a power wiring part.

Moreover, JP-A-2005-191527 discloses a water-cooling device for a plurality of semiconductor modules.

In addition, JP-A-2008-278576 discloses a composition in which a plurality of heat sinks for air cooling and a plurality of semiconductor modules are alternately laminated.

Moreover, JP-A-2008-211663 discloses a composition in which the heat of semiconductor modules is radiated from a heat sink, as well as the heat of other circuit components.

The devices disclosed in JP-A-2005-73374, JP-A-2005-191527, and JP-A-2008-278576 propose structures to cool the semiconductor modules with a large thermal output.

However, decreasing of a differential pressure inside and outside of an accommodation chamber where a circuit component of attachments such as a control circuit as a power converter etc. are accommodated is not considered.

Moreover, cooling of the circuit component of the attachments such as the control circuit as the power converter etc. is not considered, either.

Further, decreasing of the differential pressure inside and outside of the accommodation chamber is not considered either in the composition of JP-A-2008-211663.

Furthermore, since thermal outputs from a transistor for switching is large, the heat radiation from other circuit components may be disturbed.

### SUMMARY

An embodiment provides a power converter that enables a decreasing of a differential pressure inside and outside of an accommodation chamber where other circuit components are accommodated while realizing heat radiation from a switching element.

This embodiment further provides the power converter that enables the heat radiation of other circuit components while realizing heat radiation from the switching element.

In a power converter according to a first aspect, the power converter includes a plurality of switching elements in which an electric power is switched, a heat sink that cools the switching elements, a power unit that has the heat sink arranged in a ventilation path of cooling air, an accommodation chamber that accommodates a circuit component, and an attached unit that is arranged adjacent to the power unit.

A member that divides the accommodation chamber forms a passage that communicates between the ventilation path and the accommodation chamber.

According to the present disclosure, a differential pressure inside and outside of the accommodation chamber that accommodates the circuit component can be decreased by the passage while achieving heat radiation from the switching element.

Moreover, since the passage is communicated with the ventilation path of the cooling air, relatively clean air can be introduced into the accommodation chamber.

In the power converter according to a second aspect, the member that divides the accommodation chamber forms, as the passage, an entrance passage that introduces a part of the cooling air into the accommodation chamber, and an exit passage that exhausts the air from the accommodation chamber, wherein, the exit passage opens at a position downstream of an opening of the entrance passage in the ventilation path.

In the power converter according to a third aspect, the attached unit is arranged on one side of the power unit, the attached unit comprises a control unit that has a first accommodation chamber that accommodates a control circuit of the plurality of switching elements, and a capacitor unit arranged on another side of the power unit that has a second accommodation chamber that accommodates a capacitor.

A member that divides the first accommodation chamber forms a first entrance passage where a part of the cooling air is introduced into the first accommodation chamber formed as the entrance passage, and a first exit passage where the air is exhausted from the first accommodation chamber formed as the exit passage.

A member that divides the second accommodation chamber forms a second entrance passage where a part of the cooling air is introduced into the second accommodation chamber formed as the entrance passage, and a second exit passage where the air is exhausted from the second accommodation chamber formed as the exit passage.

In the power converter according to a fourth aspect, the ventilation path has an external ventilation path where the air before flowing in the power unit flows, and an internal ventilation path formed with the power unit, wherein, the entrance passage is open to the internal ventilation path.

In the power converter according to a fifth aspect, the passage has a passage that penetrates through the heat sink.

In the power converter according to a sixth aspect, the ventilation path has an external ventilation path where the air flows before flowing in the power unit, and an internal ventilation path formed with the power unit, wherein, the entrance passage is open to the external ventilation path.

In the power converter according to a seventh aspect, a filter is further disposed in the entrance passage.

### BRIEF DESCRIPTION OF THE DRAWINGS

In the accompanying drawings:

FIG. 1 shows a block diagram of a vehicle where an inverter device in a first embodiment of the present disclosure is equipped;

FIG. 2 shows a schematic diagram of the inverter device in the first embodiment;

FIG. 3 shows a perspective view that shows an exterior of the inverter device in the first embodiment;

FIG. 4 shows a perspective view of a power unit in the first embodiment;

FIG. 5 shows a perspective view that shows a disassembled state of an assembly body and elastic members in the first embodiment;

FIG. 6 shows a perspective view that shows a disassembled state of a semiconductor device in the first embodiment;

FIG. 7 shows a sectional view of the inverter device in the first embodiment;

FIG. 8 shows a sectional view of the inverter device in a second embodiment of the present disclosure;

FIG. 9 shows a sectional view of the inverter device in a third embodiment of the present disclosure;

FIG. 10 shows a front view of the power unit in a fourth embodiment of the present disclosure;

FIG. 11 shows a sectional view of the inverter device in a fifth embodiment of the present disclosure; and

FIG. 12 shows a sectional view of the inverter device in a sixth embodiment of the present disclosure.

### DETAILED DESCRIPTION OF THE PREFERRED EMBODIMENTS

With reference to the accompanying drawings, hereinafter will be described pluralities of embodiments that perform the present disclosure.

In each embodiment, components identical with or similar to those in preceding embodiments are given the same reference numerals for the sake of omitting explanation.

When only a part of the composition is explained in each embodiment, other parts of the composition of the preceding embodiments can be applied to the remaining composition.

It is not only a combination of the parts that is specified as a possible combination in each embodiment, but it is also possible to combine the parts of the embodiment mutually even if it is not specified when no obstacle is caused in the combination.

### First Embodiment

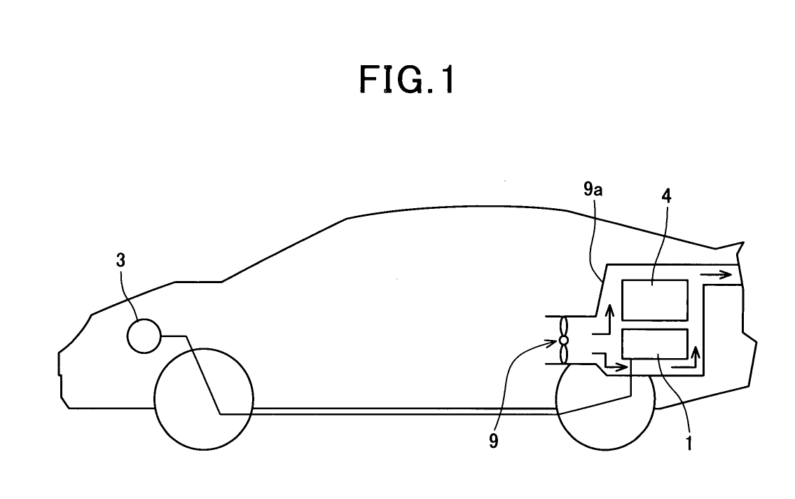

FIG. 1 shows a block diagram of a vehicle where an inverter device 1 in a first embodiment of the present disclosure is equipped.

In the first embodiment, the present disclosure is applied to the inverter device 1 as a motor driving device that drives a high power motor.

This inverter device 1 is a device that converts between direct current (DC) electric power and alternating current (AC) electric power, that is, for example, a three-phase circuit electric power converting device of U-phase, V-phase, and W-phase.

The inverter device 1 is equipped in a vehicle such as a hybrid (gas-and-electric-powered) vehicle, a fuel cell vehicle, and an electric vehicle where an AC (alternating current) motor 3 is used.

The inverter device 1 is connected so that the electric power is supplied to the motor 3 for running the vehicle equipped in the vehicle.

The inverter device 1 is arranged adjacent to a battery 4 in a rear portion of the vehicle.

The inverter device 1 and the battery 41 are arranged in a ventilation duct 9a. Cooling air is introduced in the ventilation duct 9a by a fan 9.

The inverter device 1 and the battery 4 are cooled with the air that flows in the ventilation duct 9a.

The ventilation duct 9a takes air from outside the vehicle or inside the vehicle passenger compartment, and discharges the air to outside the vehicle.

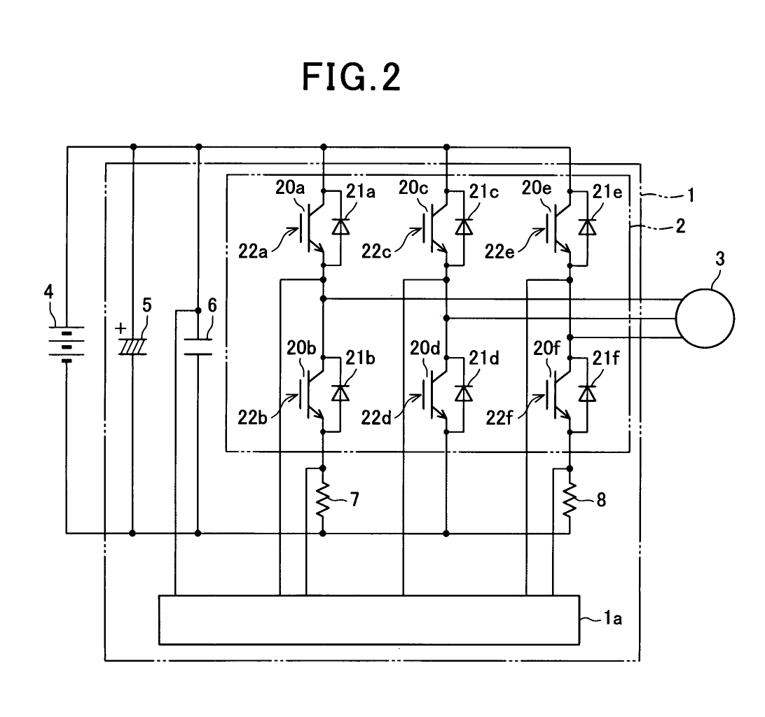

FIG. 2 shows a schematic diagram of the inverter device 1.

The inverter device 1 has a power-module 2 including a high-power switching element.

The power-module 2 is provided with a plurality of semiconductor modules 22.

In the present embodiment, six semiconductor modules 22a, 22b, 22c, 22d, 22e, and 22f are provided for the three-phase circuit electric power conversion.

Capacitors 5 and 6 and resistors 7 and 8 are included in a power circuit where the electric power between the motor 3 and the battery 4 is controlled.

In addition, the inverter device 1 has a control circuit 1a that controls the plurality of semiconductor modules 22.

The power-module 2 is controlled by the control circuit 1a, and DC electric power that the battery 4 outputs is converted into AC power and is supplied to the motor 3.

The power-module 2 is provided with IGBTs 20a, 20b, 20c, 20d, 20e and 20f as switching elements, and free-wheeling diodes 21a, 21b, 21c, 21d, 21e, and 21f and additional protection elements.

One IGBT and one free-wheeling diode are accommodated in a package, and compose one semiconductor module 22.

The control circuit 1a can input orders from the outside.

The control circuit 1a controls the power-module 2 based on a current supplied to the motor 3 from the power-module 2 that is detected by the resistors 7 and 8, and a voltage impressed to the power-module 2 from the battery 4 that is detected by the capacitor 6.

The control circuit 1a is connected to the power-module 2, the resistors 7 and 8, and the capacitors 6.

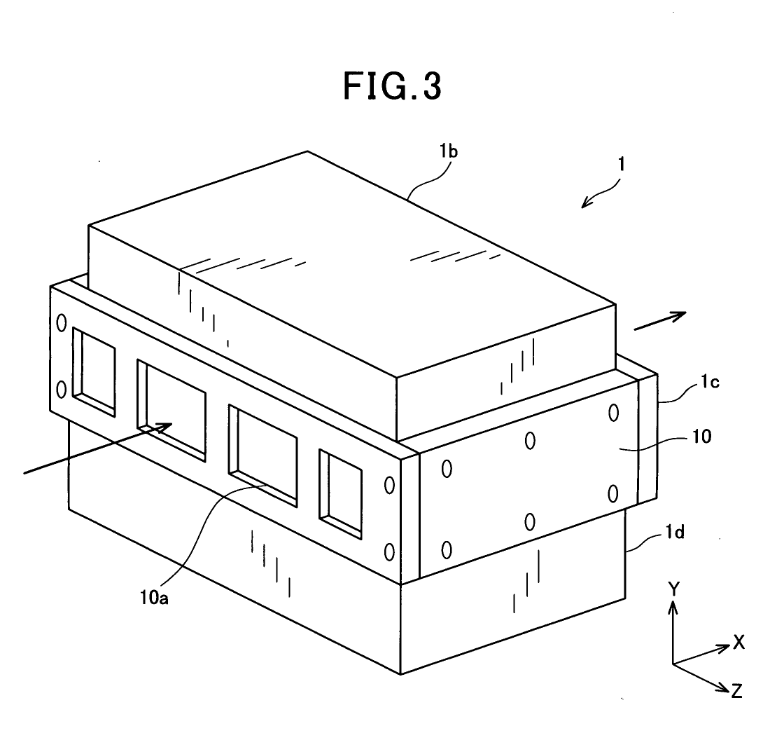

FIG. 3 shows a perspective view that shows an exterior of the inverter device.

The inverter device 1 has a control unit 1b that accommodates the control circuit 1a, a power unit 1c that accommodates the power-module 2, and a capacitor unit 1d that accommodates the capacitors and high-voltage wirings.

The power unit 1c is arranged between the control unit 1b and the capacitor unit 1d.

The power unit 1c accommodates the power-module 2 in a case 10.

The power unit 1c is an air-cooled type power converter that accommodates a plurality of semiconductor modules and a plurality of heat sinks that cool the semiconductor modules in the case.

Ventilation openings 10a as entrances and exits of the air connected to the ventilation duct 9a are provided on opposing sides of the case 10.

Although not shown in the figures, the inverter device 1 has a plurality of external connecting terminals, electric power terminals and connectors, for example.

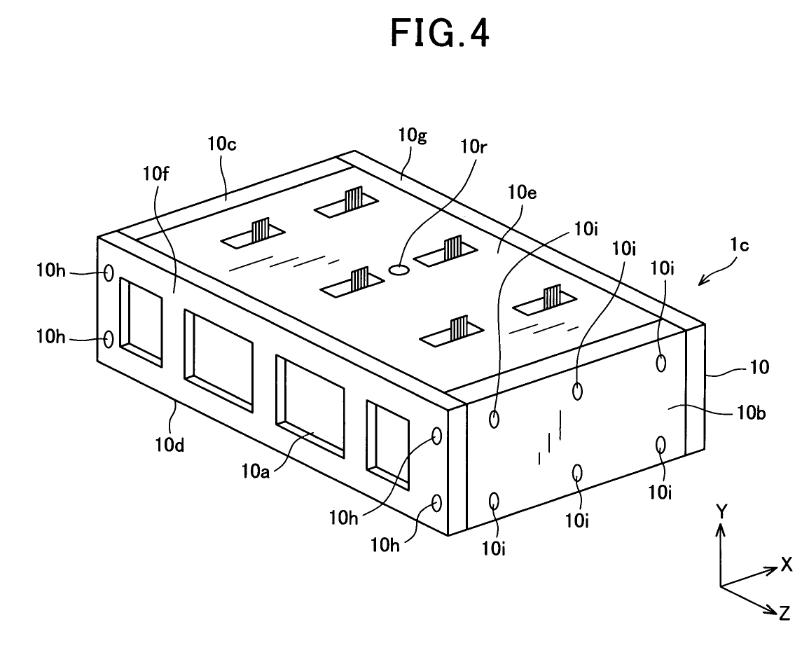

FIG. 4 shows a perspective view of the power unit 1c.

The case 10 is a box made of six plates being assembled.

The case 10 has two side plates 10b, 10c, a bottom plate 10d, a top plate 10e, and two grid plates 10f, 10g.

A plurality of openings for penetrating and arranging the terminals is formed on the bottom plate 10d.

A plurality of openings for penetrating the terminals is formed on the top plate 10e.

The ventilation openings 10a as the entrances and the exits of the air are formed on the grid plates 10f and 10g.

The grid plate 10f and the grid plate 10g have symmetric shapes.

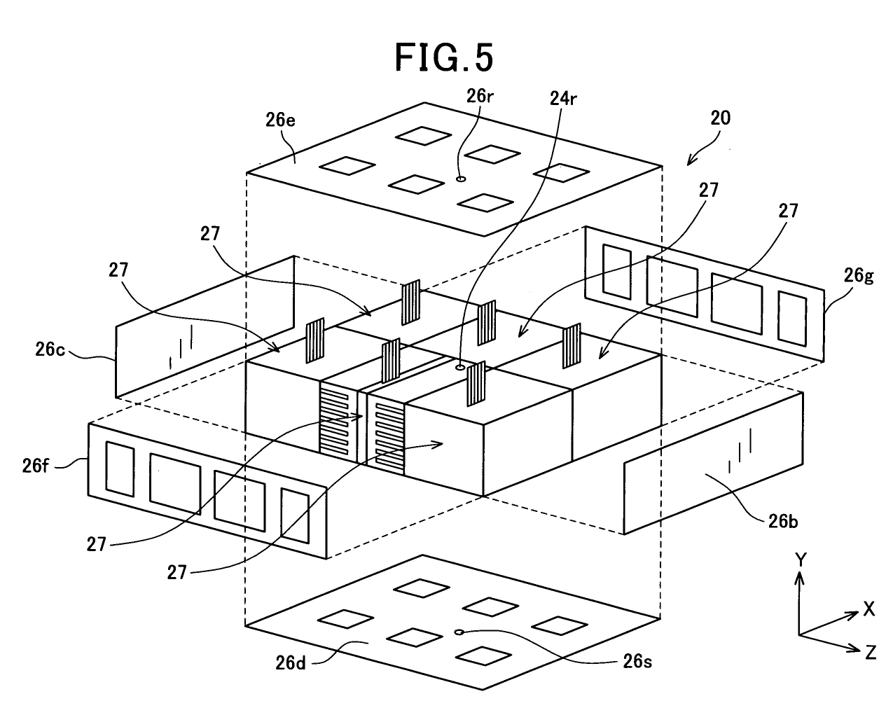

FIG. 5 shows a perspective view that shows a disassembled state of an assembly body 20 and elastic members 26 of the power-module 2.

The assembly body 20 is provided with a plurality of semiconductor devices 27 arranged in a matrix.

The semiconductor devices 27 are arranged in a matrix with 2 lines×3 rows.

In order to suppress the temperature differences in an upstream side and a downstream side of the lines, the plurality of semiconductor devices 27 is preferred to be arranged in two lines.

The elasticity members 26 that elastically support the assembly body 20 in a direction of at least one axis are disposed between the assembly body 20 and the case 10.

In the embodiment as shown in the figure, the elasticity members 26 are disposed in the direction of three axes.

The direction of three axes corresponds to ventilation direction X, a vertical direction Y, and a laminating direction Z as the power unit 1c.

The plate-like elasticity members 26 are arranged between the assembly body 20 and the case 10.

The elasticity members 26 are of an electrically insulating material. The elasticity members 26 are made of, for example, resin or rubber.

The elasticity member 26b is arranged between the assembly body 20 and the side plate 10b.

The elasticity member 26c is arranged between the assembly body 20 and the side plate 10c.

The elasticity member 26d is arranged between the assembly body 20 and the bottom plate 10d.

The elasticity member 26d has the size that expands and covers the bottom surfaces of all the semiconductor devices 27.

A plurality of holes to penetrate the terminals is open to the elasticity member 26d.

The elasticity member 26e is arranged between the assembly body 20 and the top plate 10e.

The elasticity member 26e has the size that extends and covers the top surfaces of all semiconductor devices 27.

A plurality of holes to penetrate the terminals is open to the elasticity member 26e.

The elasticity member 26f is arranged between the assembly body 20 and the grid plate 10f.

The elasticity members 26g is arranged between the assembly body 20 and the grid plate 10g.

The openings corresponding to the ventilation openings 10a are formed in the elasticity members 26f and 26g.

As a result, the elasticity members 26 are arranged on the six sides of the hexahedron assembly bodies 20.

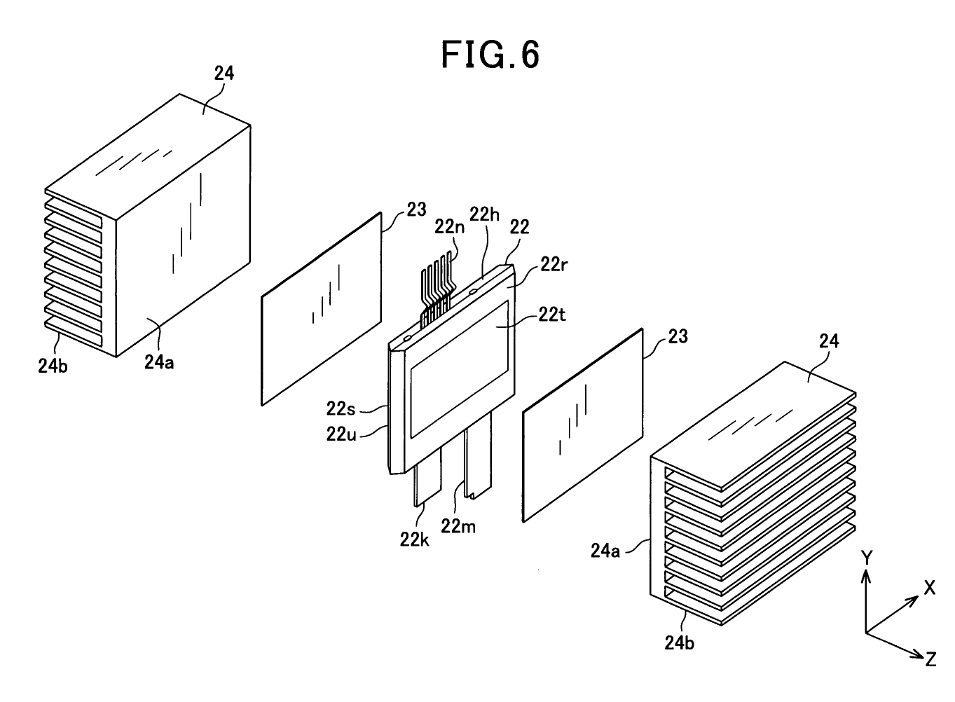

FIG. 6 shows a perspective view that shows a disassembled state of one semiconductor device 27.

The semiconductor module 22 has a package 22h, a collector side electrode terminal 22k, an emitter side electrode terminal 22m, and a plurality of control signal terminals 22n.

The package 22h has a shape that can be called a card shape or tabular shape. The package 22h is composed by molding a semiconductor element with epoxy resin.

Metallic heat exchange plates 22t and 22u for heat radiation are arranged in an exposed manner at approximately the center of both main surfaces 22r and 22s of the package 22h.

The semiconductor device 27 provides the air-cooled type semiconductor element unit that can cool the semiconductor module 22 from both sides.

One of the IGBTs 20a-20f and one of the free-wheeling diodes 21a-21f are built into the semiconductor module 22.

The collector side electrode terminal 22k, the emitter side electrode terminal 22m, and the plurality of control signal terminals 22n are extended from the sides of the package 22h parallel to the main surfaces 22r and 22s.

The collector side electrode terminal 22k and the emitter side electrode terminal 22m are projected from one side of the package 22h.

The plurality of control signal terminals 22n are projected from an opposite side of the package 22h.

The control signal terminals 22n are extending toward the control unit 1b, and are connected to the control circuit 1a.

The electrode terminals 22k and 22m are extending toward the capacitor unit 1d, and are connected to electric power circuit parts.

Therefore, the plurality of semiconductor modules are arranged to connect between the control unit 1b and the capacitor unit 1d.

The IGBT and the free-wheeling diode accommodated in the package 22h is arranged between the metallic heat exchange plate 22t and the metallic heat exchange plates 22u.

The IGBT and the free-wheeling diode are connected via the solder layer to both the heat exchange plate 22t and the metallic heat exchange plate 22u.

An anode and a cathode of the free-wheeling diode are connected with the collector and the emitter of IGBT in a so-called parallel-in-reverse direction in the package 22h.

The metallic heat exchange plate 22t and the metallic heat exchange plate 22u are electrically connected to the collector side electrode terminal 22k and the emitter side electrode terminal 22m, respectively.

Moreover, the above-mentioned solder layer may be substituted for other joint function materials.

A plurality of heat sinks 24 are all formed in the same shape. The heat sink 24 is made of aluminum alloy.

The heat sink 24 has a plate-like base plate 24a and a plurality of fins 24b. The base plate 24a is a flat plate that extends along the ventilation direction X and the vertical direction Y.

The base plate 24a is arranged parallel to and closer to the semiconductor module 22 so that the heat of the semiconductor module 22 may be transferred to the base plate 24a.

The fins 24b are formed with the base plate 24a unitarily expanding vertically from the base plate 24a.

Each fin 24b is a flat plate that extends along the ventilation direction X and the laminating direction Z.

Spaces where the cooling air flows are provided between the adjoining fins 24b.

In another words, the heat sink 24 is a block material having a comb-like section.

In insulation base plate 23 that is made of ceramic is arranged between the package 22h and the heat sink 24.

A silicon type heat radiating grease that has a good thermal conductivity is spread between the insulation base plate 23 and the heat sink 24, and between the insulation base plate 23 and the package 22h.

Moreover, the insulation base plate 23 may be formed with a nitride aluminum film or a silicon rubber seat.

The insulation base plate 23 and the heat radiating grease may be provided with a heat radiation film that has no electrical conductivity.

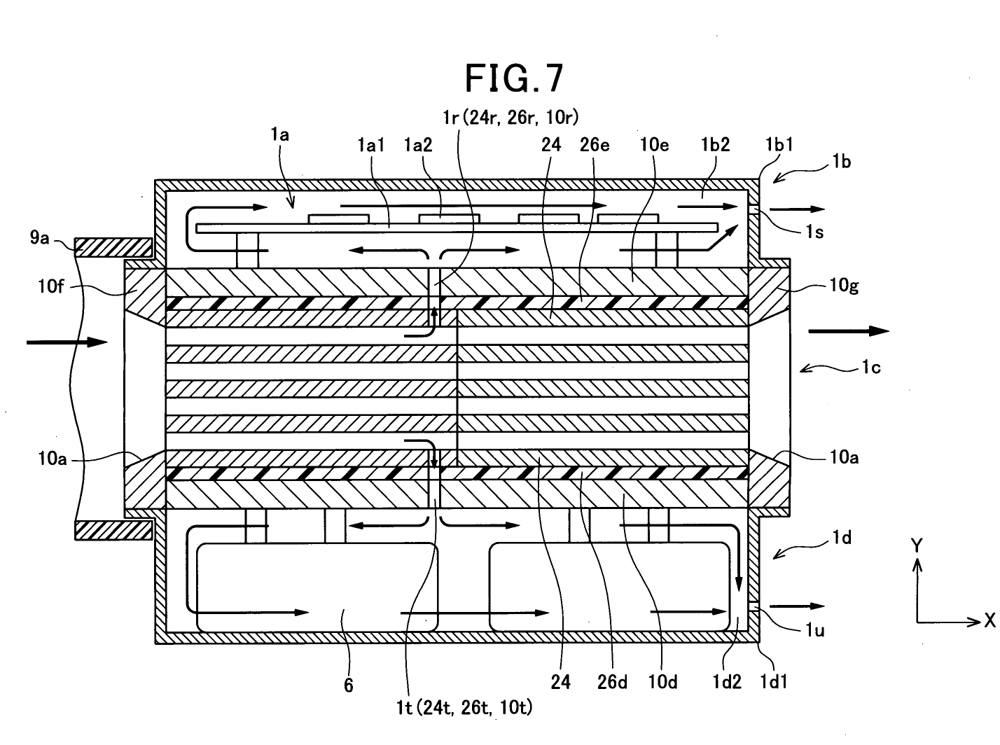

An air flowing structure is explained in detail referring to FIG. 4, FIG. 5, and FIG. 7.

FIG. 7 is a cross sectional view of the inverter device 1 in an X-Y plane.

The control unit 1b and the capacitor unit 1d are attached units.

The control unit 1b is arranged on one side of the power unit 1c.

The capacitor unit 1d is arranged on another side of the power unit 1c.

The power unit 1c supports the plurality of the heat sinks 24 of the plurality of semiconductor devices 27.

The plurality of heat sinks 24 are arranged in the power unit 1c so as to expose to a ventilation path where the cooling air flows.

The ventilation path includes an internal ventilation path formed within the power unit 1c, and external ventilation paths formed on an upstream side and a downstream side of the power unit 1c.

The external ventilation path on the upstream side of the power unit 1c is provided by the ventilation duct 9a, and can be called as an upstream side ventilation path.

The control unit 1b has a case 1b1 and the top plate 10e as parts that divide an accommodation chamber 1b2.

The control circuit 1a is accommodated in the accommodation chamber 1b2. The control circuit 1a has a circuit plate 1a1 and a plurality of circuit parts 1a2 mounted on the circuit plate 1a1.

Spaces that allow the air to flow are formed along both sides of the circuit plate 1a1.

The accommodation chamber 1b2 may be called a first accommodation chamber or a control circuit accommodation chamber.

The control unit 1b has an air-flowing structure for the ventilation of the accommodation chamber 1b2, and for cooling the circuit parts 1a2.

The capacitor unit 1d has a case 1d1 and the bottom plate 10d as parts that divide an accommodation chamber 1d2.

A circuit component of an electric power system including the plurality of capacitors 6 is accommodated in the accommodation chamber 1d2.

The accommodation chamber 1d2 may be called a second accommodation chamber or a capacitor accommodation chamber.

The capacitor unit 1d has an air-flowing structure for the ventilation of the accommodation chamber 1d2, and for cooling the circuit component of the electric power system.

The air-flowing structure of the control unit 1b is provided by an entrance passage 1r and an exit passage 1s.

The entrance passage 1r and the exit passage 1s are formed in the parts 1b1, 10e, 26e, and 24 that divide the accommodation chamber 1b2.

The entrance passage 1r introduces the air supplied from the ventilation duct 9a into the accommodation chamber 1b2.

As a result, relatively clean air is introduced into the accommodation chamber 1b2.

The entrance passage 1r may be called a first entrance passage c while the exit passage 1s may be called a first exit passage 1s.

One end of the entrance passage 1r is open to the ventilation path of the cooling air.

In the present embodiment, the one end of the entrance passage 1r is open to the internal ventilation path.

The entrance passage 1r introduces the air from the ventilation path between the fins 24b.

The entrance passage 1r is provided with a passage 24r that penetrates an edge most fin 24b of the heat sink 24, a passage 26r that penetrates the elasticity members 26e, and a passage 10r that penetrates the top plate 10e. The passages 24r, 26r, and 10r are through holes.

Another end of the entrance passage 1r is open to the accommodation chamber 1b2. The entrance passage 1r is so open to a central area in the X-Z plane of the control unit 1b.

The entrance passage 1r is open to the space between the circuit plate 1a1 and the top plate 10e.

The circuit parts 1a2 having relatively high thermal outputs are arranged near the entrance passage 1r in the control circuit 1a.

As a result, the circuit parts 1a2 are cooled relatively well.

The exit passage 1s exhausts the air in the accommodation chamber 1b2 to outside the accommodation chamber 1b2.

The exit passage 1s is open to the case 1b1.

The exit passage 1s is open to a position away from the entrance passage 1r.

The exit passage 1s is open to a position downstream of the opening of the entrance passage 1r in the ventilation path.

The air-flowing structure of the capacitor unit 1d is provided by the entrance passage 1t and the exit passage 1u.

The entrance passage 1t and the exit passage 1u are formed by the parts 1d1, 10d, 26d, and 24 that divide the accommodation chamber 1d2.

The entrance passage 1t introduces the air supplied from the ventilation duct 9a into the accommodation chamber 1db2.

As a result, a relatively clean air is introduced into the accommodation chamber 1d2.

The entrance passage 1t may be called a second entrance passage 1t, while the exit passage 1u may be called a second exit passage 1u.

One end of the entrance passage 1t is open to the ventilation path of the cooling air.

In the present embodiment, the one end of the entrance passage 1t is open to the internal ventilation path.

The entrance passage 1t introduces the air from the ventilation path between the fins 24b.

The entrance passage 1t is provided with a passage 24t that penetrates an edge most fin 24b of the heat sink 24, a passage 26t that penetrates the elasticity members 26d, and a passage 10t that penetrates the bottom plate 10r. The passages 24t, 26t, and 10t are through holes.

Another end of the entrance passage 1t is open to the accommodation chamber 1d2. The entrance passage 1t is open to a central area in the X-Z plane of the capacitor unit 1d.

The exit passage 1u exhausts the air in the accommodation chamber 1d2 to outside the accommodation chamber 1d2.

The exit passage 1u is open to the case 1d1.

The exit passage 1u is open to a position away from the entrance passage 1t.

The exit passage 1u is open to a position downstream of the opening of the entrance passage 1t in the ventilation path.

Sectional areas as the passages in the entrance passage 1r and the exit passage 1s, and sectional areas as the passage in the entrance passage 1t and the exit passage 1u are set to extent in which an amount of the air flow that flows on the heat sink 24 is not greatly decreased.

The sectional areas as the passages in the entrance passage 1r and the exit passage 1s are set to pass a few air.

The sectional areas as the passages in the entrance passage 1t and the exit passage 1u are set to pass a few air.

For example, the sectional areas of the entrance passage 1r and 1t can be set to about 1/10- 1/1000 of a sectional area of the ventilation path in the power unit 1c.

Moreover, the sectional areas of the exit passage 1s and 1u can be set to about 1/10- 1/100 of passage sectional areas of the passages 24r and 24t formed on the fins 24b.

When the inverter device 1 controls the electric power that is supplied to the motor 3, the heat generated in the semiconductor module 22 is conducted to the heat sinks 24.

On the other hand, the cooling air is ventilated in the ventilation duct 9a by the fan 9.

The air flows into the power unit 1c from the ventilation openings 10a of the grid plate 10f.

The air flows on the surface of all the heat sinks 24 in the power unit 1c.

At this time, the air cools the heat sinks 24.

The air flows outside the power unit 1c from the ventilation openings 10a of the grid plate 10g.

In addition, the air is introduced from the ventilation path between the fins 24b into the accommodation chamber 1b2 via the entrance passage 1r.

The air expands along the circuit plate 1a1 while cooling the circuit parts lag located in an extended position of the entrance passage 1r.

A part of the air flows between the circuit plate 1a1 and the top plate 10e towards the exit passage 1s.

The remaining air flows between the circuit plate 1a1 and the case 1b1 towards the exit passage 1s after flowing between the circuit plate 1a1 and the top plate 10e.

By this, the air flows inside the whole accommodation chamber 1b2.

As a result, the air-flowing structure of the control unit 1b assists heat radiation from the control circuit 1a.

Moreover, the air-flowing structure of the control unit 1b decreases the differential pressure outside the accommodation chamber.

Further, the air is introduced from the ventilation path between the fins 24b into the accommodation chamber 1d2 via the entrance passage 1t.

The air flows towards the exit passage 1u while cooling the capacitor 6 as the circuit component.

By this, the air flows inside the whole accommodation chamber 1d2.

As a result, the air-flowing structure of the capacitor unit 1d assists heat radiation from the capacitor 6.

Moreover, the air-flowing structure of the capacitor unit 1d decreases the differential pressure outside the accommodation chamber.

### Second Embodiment

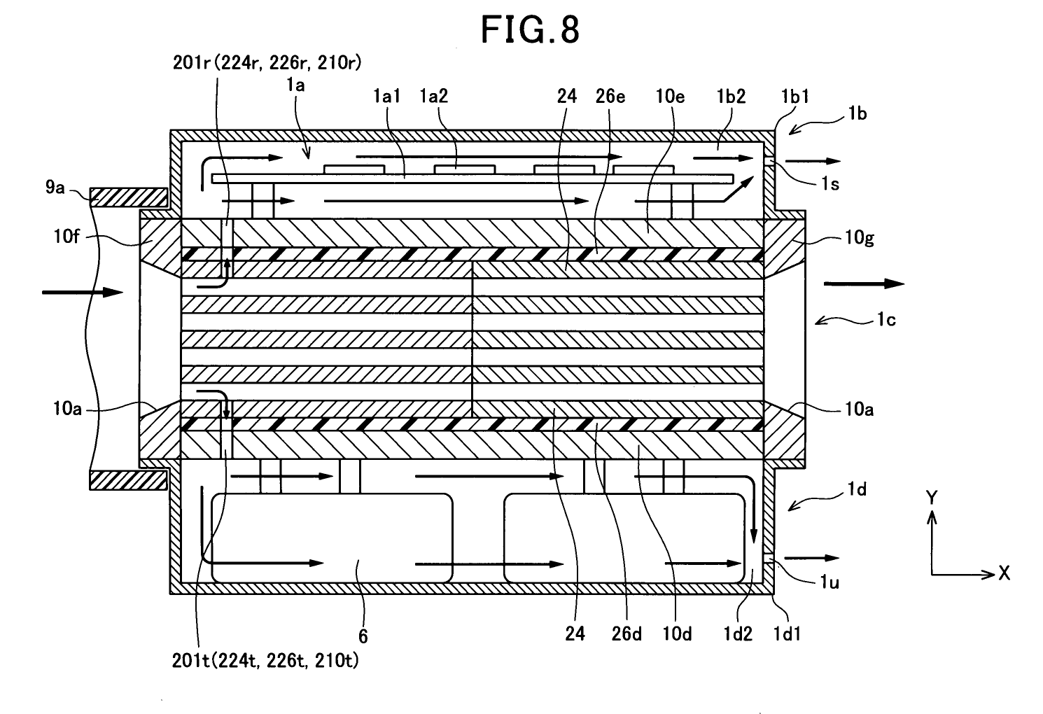

FIG. 8 shows a sectional view of the inverter device 1 in a second embodiment of the present disclosure.

In the present embodiment, entrance passages 201r and 201t are provided in place of the entrance passages 1r and 1t.

The entrance passage 201r is provided by a passage 224r formed in the edge most fin 24b of one heat sink 24, a passage 226r formed in the elasticity member 26e, and a passage 210r formed in the top plate 10e.

An end of the entrance passage 201r is open to the upstream area of the internal ventilation paths.

Moreover, another end of the entrance passage 201r is open to an end part of the accommodation chamber 1b2.

The end part is located roughly on an opposite position relative to the exit passage 1s.

Even in the present embodiment, the circuit parts 1a2 with relatively large thermal outputs can be arranged near the entrance passage 201r.

For example, it is preferable to arrange high heat generating parts such as integrated circuits for driving the load, microcomputers, and integrated circuits for power supplies near the entrance passage 201r.

The entrance passage 201t is provided by a passage 224t formed in the edge most fin 24b of one heat sink 24, a passage 226t formed in the elasticity member 26e, and a passage 210t formed in the top plate 10e.

An end of the entrance passage 201t is open to the upstream area of the internal ventilation paths.

Moreover, another end of the entrance passage 201t is open to an end part of the accommodation chamber 1d2.

The end part is located roughly on an opposite position relative to the exit passage 1u.

According to the present embodiment, the air flows from one end of the accommodation chamber to another end.

Therefore, the air can be passed without causing a large dead area in the accommodation chamber.

### Third Embodiment

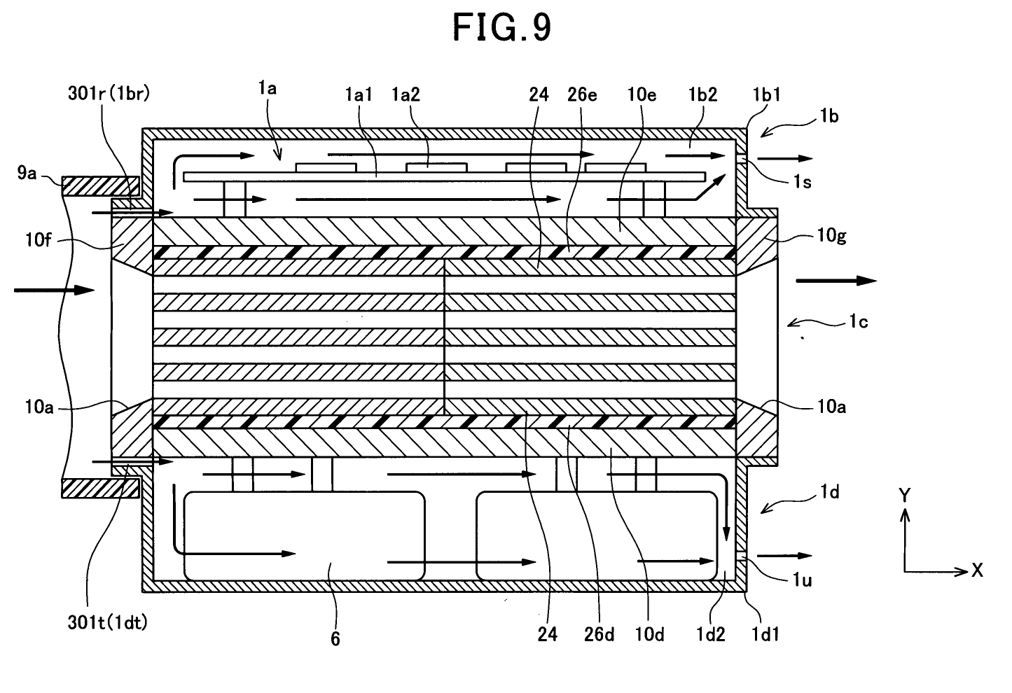

FIG. 9 shows a sectional view of the inverter device 1 in a third embodiment of the present disclosure.

In the present embodiment, entrance passages 301r and 301t are provided in place of the entrance passages 1r and 1t.

The entrance passage 301r is provided with a passage 1br formed between the case 1b1 and the grid plate 10f that is a part of the case 10.

In order to form the passage 1br, a slot-shaped concave portion is formed in the case 1b1.

An end of the entrance passage 301r is open to the external ventilation path, that is, in the upstream side ventilation path.

The entrance passage 301t is provided with a passage 1bt formed between the case 1d1 and the grid plate 10f that is a part of the case 10.

In order to form the passage 1dt, a slot-shaped concave portion is formed in the case 1t1.

An end of the entrance passage 301t is open to the external ventilation path, that is, in the upstream side ventilation path.

According to the present embodiment, the air-flowing structure can be provided while decreasing the processing of the through holes.

### Fourth Embodiment

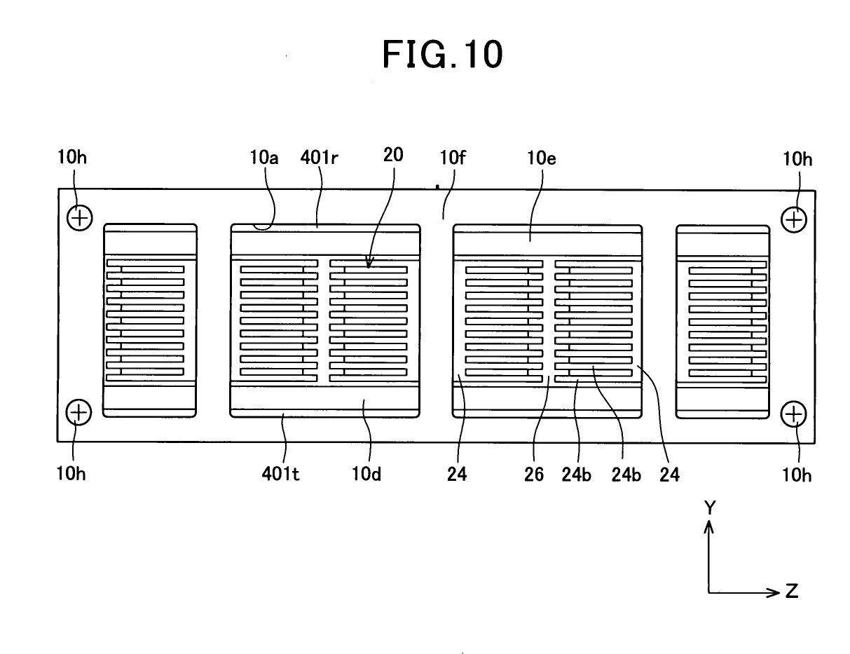

FIG. 10 shows a front view of the power unit 1c in a fourth embodiment of the present disclosure;

The grid plate 10f is tightened, and fixed to the side plates 10b and 10c with screws 10h.

As shown in the figure, the assembly body 20 of the power-module 2 accommodated in the case 10 can be seen from the ventilation openings 10a.

In the present embodiment, the elasticity member 26 is arranged between two adjoining heat sinks 24.

The elasticity member 26 is also arranged between the heat sink 24 and the bottom plate 10d, and between the heat sink 24 and the top plate 10e.

The elasticity member 26 engages with the fins 24b of the heat sink 24.

In the present embodiment, entrance passages 401r and 401t are provided in place of the entrance passages 1r and 1t.

An end surface of the top plate 10e and an end surface of the bottom plate 10d are exposed in the ventilation openings 10a of the grid plate 10f.

An upstream side opening of the entrance passage 401r is exposed to the ventilation openings 10a

The entrance passage 401r is communicated to the accommodation chamber 1b2.

The upstream side opening is opened like a slit-like opening.

An upstream side opening of the entrance passage 401t is exposed to the ventilation openings 10a

The entrance passage 401t is communicated to the accommodation chamber 1d2.

The upstream side opening is opened like a slit.

According to the present embodiment, wide entrance passages 401r and 401t that spread over the width of the accommodation chambers 1b2 and 1d2 can be provided.

### Fifth Embodiment

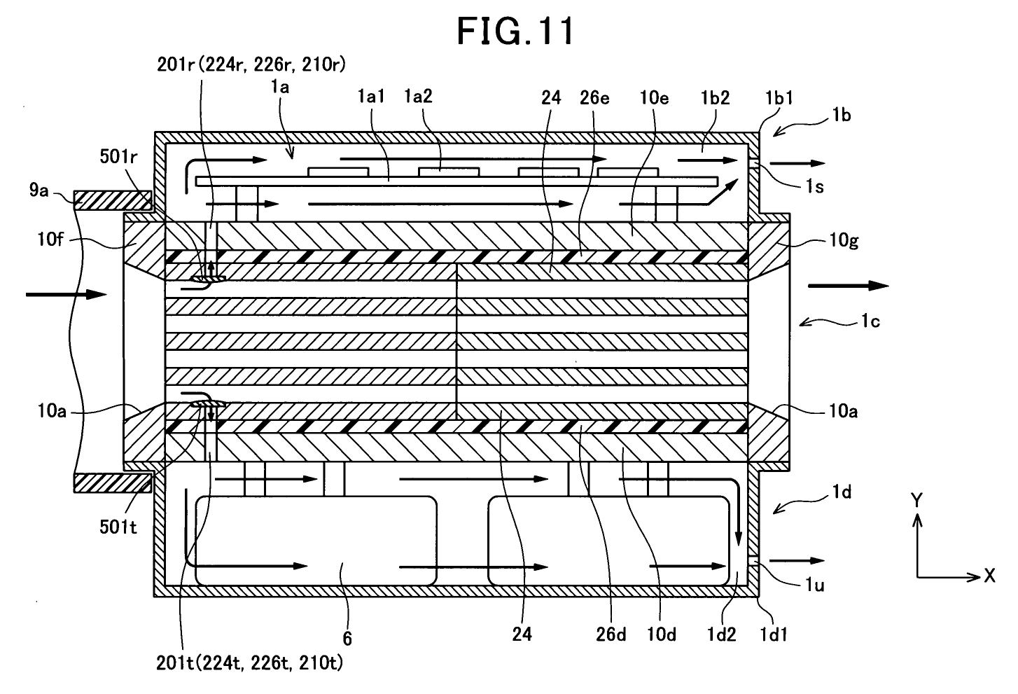

FIG. 11 shows a sectional view of the inverter device 1 in a fifth embodiment of the present disclosure.

In the present embodiment, filters 501r and 501t are disposed to the entrance passages 201r and 201t.

The filters 501r and 501t prevent foreign matter such a drop of water or dust from entering into the accommodation chamber by filtering the air that passes.

In addition, surfaces in the entrance side of the filters 501r and 501t are arranged in parallel with the direction of ventilation air flow.

Therefore, the adhesion of the foreign matter is decreased.

### Sixth Embodiment

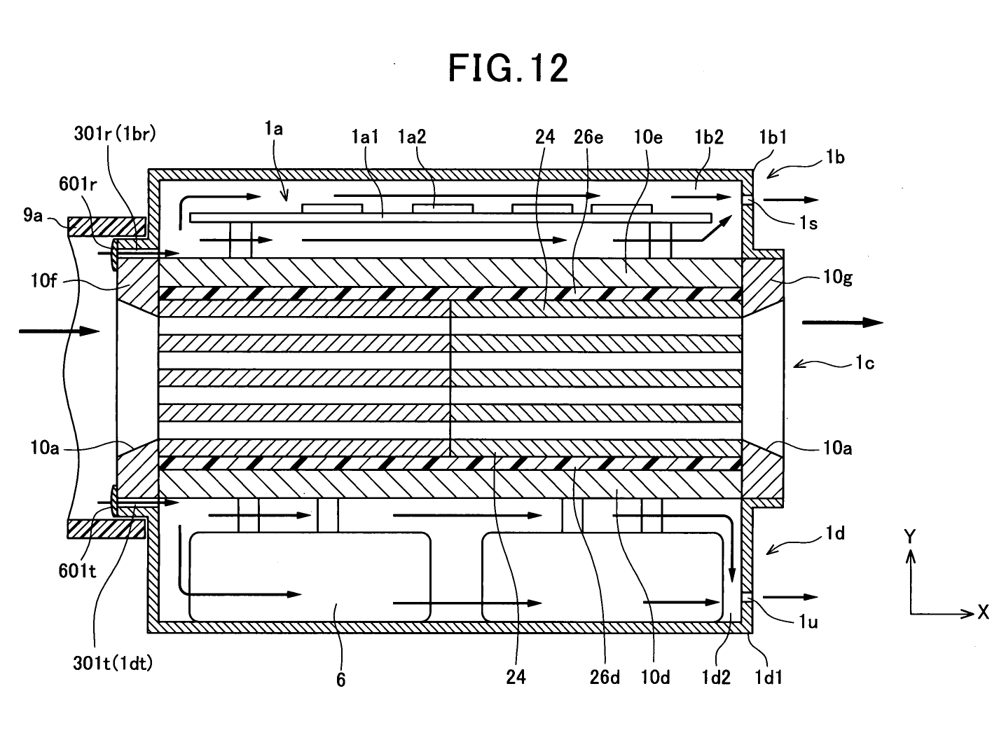

FIG. 12 shows a sectional view of the inverter device 1 in a sixth embodiment of the present disclosure.

In the present embodiment, filters 601r and 601t are disposed to the entrance passages 301r and 301t.

The filters 601r and 601t prevent foreign matter such a drop of water or dust from entering into the accommodation chamber by filtering the air that passes.

### Other Embodiments

Although preferable embodiments of the present disclosure are explained above, the present disclosure is not limited to the above-mentioned embodiments, and a variety of modifications within the range in which it does not deviate from the purpose of the present disclosure can be performed.

The structures in the above-mentioned embodiments are examples, and the range of the present disclosure is not limited within the range of the disclosures.

The range of the present disclosure is given in the claims, and, in addition, is including all modifications within the meaning and range equivalent to the description of the claims.

Although the passages 24r, 26r, 10r, 24t, 26t, 10t, 224r, 226r, 210r, 224t, 226t, and 210t that provide the entrance passages 1r, 1t, 201r and 201t are through holes in the above-mentioned embodiments, the passages can be provided as slots or gaps.

For example, a part of the entrance passage can be provided by a gap between two adjoining heat sinks 24 in place of the passage 24r.

Although IGBT for the high output is formed as the semiconductor tip in the above-mentioned embodiment, a semiconductor tip with MOSFET and JFET, etc. for the low output may be used.

The usage of the motor driven by the inverter device in the above-mentioned embodiment does not limit to the running of the vehicle, but to operate power generator, an engine starter, or to drive accessory devices such as compressors, etc. Further, driving a plurality of motors according to the usage and a necessary ability may be performed, and may be provided with the inverter device stuck into a plurality of steps.

What is claimed is:

1. A power converter comprising:
a plurality of switching elements in which an electric power is switched;
a heat sink that cools the switching elements;
a power unit that has the heat sink arranged in a ventilation path of cooling air;
an accommodation chamber that accommodates a circuit component; and
an attached unit that is arranged adjacent to the power unit;
wherein, a member that divides the accommodation chamber forms a passage that communicates between the ventilation path and the accommodation chamber.

2. The power converter according to claim 1, wherein,
the member that divides the accommodation chamber forms, as the passage, an entrance passage that introduces a part of the cooling air into the accommodation chamber, and an exit passage that exhausts the air from the accommodation chamber,
wherein, the exit passage opens at a position downstream of an opening of the entrance passage in the ventilation path.

3. The power converter according to claim 2, wherein,
the attached unit is arranged on one side of the power unit,
the attached unit comprises a control unit that has a first accommodation chamber that accommodates a control circuit of the plurality of switching elements, and
a capacitor unit arranged on another side of the power unit that has a second accommodation chamber that accommodates a capacitor, wherein,
a member that divides the first accommodation chamber forms a first entrance passage where a part of the cooling air is introduced into the first accommodation chamber formed as the entrance passage, and
a first exit passage where the air is exhausted from the first accommodation chamber formed as the exit passage, and
a member that divides the second accommodation chamber forms a second entrance passage where a part of the cooling air is introduced into the second accommodation chamber formed as the entrance passage, and
a second exit passage where the air is exhausted from the second accommodation chamber formed as the exit passage.

4. The power converter according to claim 2, wherein,
the ventilation path has an external ventilation path where the air flows before flowing in the power unit, and an internal ventilation path formed with the power unit, wherein,
the entrance passage is open to the internal ventilation path.

5. The power converter according to claim 4, wherein,
the passage has a passage that penetrates through the heat sink.

6. The power converter according to claim 2, wherein,
the ventilation path has an external ventilation path where the air before flowing in the power unit flows, and an internal ventilation path formed with the power unit, wherein,
the entrance passage is open to the external ventilation path.

7. The power converter according to claim 2, wherein,
a filter is further disposed in the entrance passage.
